(19) United States
(12) Patent Application Publication
(10) Pub. No.: US 2012/0068783 A1
(43) Pub. Date: Mar. 22, 2012

(54) Tuning Circuit For Pivotal Antenna

(75) Inventors: Tsung-Wen Chiu, Taipei County (TW); Fu-Ren Hsiao, Taipei County (TW)

(73) Assignee: ADVANCED CONNECTEK, INC., Taipei County (TW)

(21) Appl. No.: 12/973,436

(22) Filed: Dec. 20, 2010

(30) Foreign Application Priority Data
Sep. 17, 2010 (TW) 099131558

(51) Int. Cl. H03H 7/38

(52) U.S. Cl. 333/33

(57) ABSTRACT

A tuning circuit for a pivotal antenna comprises a feeder transmission cable, a microwave medium, an impedance-matching tuning circuit, a grounding plane, a pivotal shaft, a radiation conductor, and a carrier member. The feeder transmission cable has a central wire and an outer conductor. The microwave medium has a first plane and a second plane. The impedance-matching tuning circuit is arranged on the first plane and connected with the central wire. The grounding plane is arranged on the second plane and connected with the outer conductor. The pivotal shaft has a first end connected with the impedance-matching tuning circuit and a second end connected with the radiation conductor. The carrier member accommodates the microwave medium thereinside. The tuning circuit for a pivotal antenna of the present invention can provide superior impedance and bandwidth for a radiation conductor of an antenna.

### BACKGROUND OF THE INVENTION

1. Field of the Invention

The present invention relates to a tuning circuit for a pivotal antenna, particularly to a tuning circuit whose chip is integrated with a wireless transmission device having a pivotal shaft.

2. Description of the Related Art

Wireless communication products play import roles in modern daily life, such as portable computers, mobile phones, vehicle satellite navigation devices. They are wirelessly linked to another device via antennae that transceive electromagnetic wave in space.

Antenna gain is a factor crucial to the performance of an antenna. How to layout an antenna inside an electronic device is a critical problem to upgrade the electromagnetic transmission efficiency of the antenna. Many wireless transmission devices belong to a pivotal-type design, wherein the radiation conductor is disposed in the border of the frame. However, the elbow region of the pivotal device may cause noise or interruption of radiation signals, and generates null points of the radiation pattern. Thus is decreased the antenna gain and signal intensity and greatly affected the transmission efficiency of wireless signals. In order to overcome the abovementioned problems, the researchers are eager to develop a technology to simultaneously increase the impedance of the elbow region, the bandwidth of the antenna, and the gain of the antenna.

### SUMMARY OF THE INVENTION

One objective of the present invention is to provide a tuning circuit for a pivotal antenna, wherein a chip of an impedance-matching tuning circuit is integrated with a metal-plate element of a pivotal wireless device to make the radiation conductor of the antenna have superior impedance and bandwidth, and increase the antenna gain and signal intensity, whereby is maintained the efficiency and stability of signal transmission.

Another objective of the present invention is to provide a tuning circuit for a pivotal antenna, wherein a pivotal shaft and a metal plate of a notebook computer or a mobile phone are integrated to greatly increase the transmission area of the radiation conductor, whereby is increased signal intensity and operating bandwidth.

To achieve the abovementioned objectives, the present invention proposes a tuning circuit for a pivotal antenna, which comprises a feeder transmission cable, a microwave medium, an impedance-matching tuning circuit, a grounding plane, a pivotal shaft, a radiation conductor, and a carrier member. The feeder transmission cable has a central wire and an outer conductor. The microwave medium has a first plane and a second plane. The impedance-matching tuning circuit is arranged on the first plane and connected with the central wire. The grounding plane is arranged on the second plane and connected with the outer conductor. The pivotal shaft has a first end and a second end. The first end of the pivotal shaft is connected with the impedance-matching tuning circuit, and the second end of the pivotal shaft is connected with the radiation conductor. The carrier member accommodates the microwave medium thereinside.

The present invention is characterized in that the chip of a tuning circuit chip is integrated with a wireless transmission device having a pivotal shaft. The chip of an impedance-matching tuning circuit can effectively feed high-frequency signals to the pivotal shaft and then to a metal plate of a notebook computer or a mobile phone. Thereby, the tuning circuit chip, pivotal shaft and metal plate are integrated to effectively promote the performance of the antenna system.

Further, the present invention fine-tunes the size of the pivotal element and modifies the connection position of the adjacent elements and the area of the metal plate to make the radiation conductor of an antenna have superior impedance, bandwidth and radiation pattern and increase the operating bandwidth, radiation efficiency, and wireless transmission capability of the antenna.

Below, the embodiments are described in detail to make easily understood the technical contents of the present invention.

### BRIEF DESCRIPTION OF THE DRAWINGS

FIG. 1 is a partially-enlarged perspective view schematically showing that a tuning circuit for a pivotal antenna is applied to a portable computer according to a first embodiment of the present invention;

FIG. 2 is a perspective exploded view according to the first embodiment of the present invention.

FIG. 3 is a perspective assembly drawing according to the first embodiment of the present invention;

FIG. 4 is a flowchart according to the first embodiment of the present invention;

FIG. 5 is a diagram showing the measurement results of the voltage standing wave ratio (VSWR) of the tuning circuit for a pivotal antenna according to the first embodiment of the present invention; and

FIG. 6 is a partially-enlarged perspective view schematically showing that the tuning circuit for a pivotal antenna of the present invention is applied to a portable computer according to a second embodiment of the present invention.

### DETAILED DESCRIPTION OF THE INVENTION

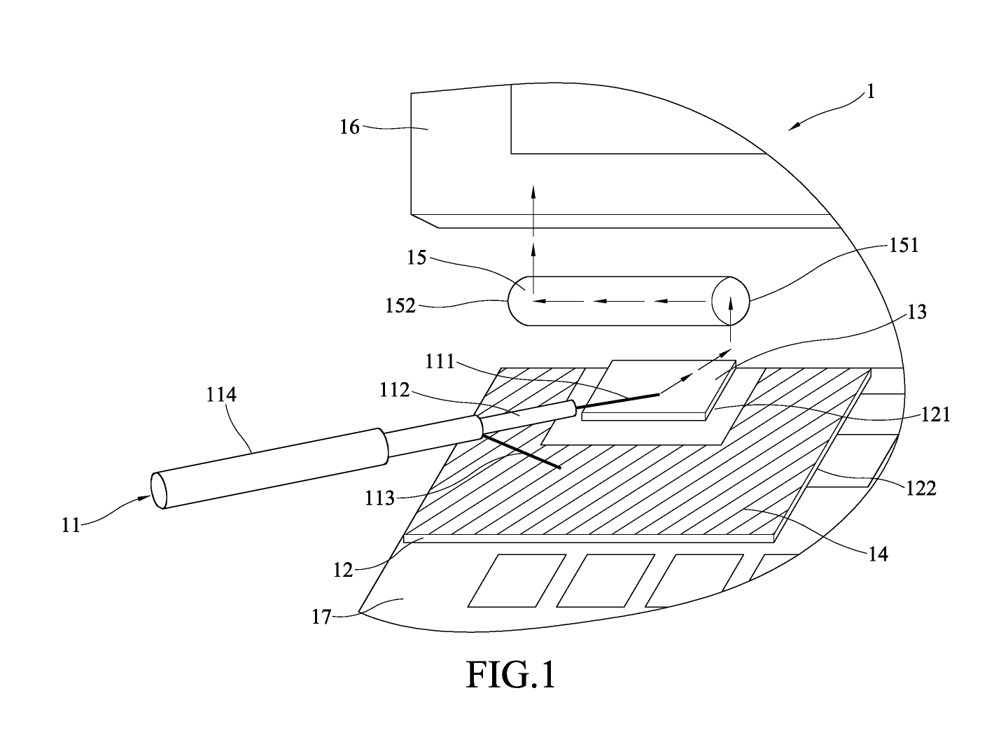

Refer to FIG. 1 a partially-enlarged perspective view schematically showing that a tuning circuit for a pivotal antenna is applied to a portable computer according to a first embodiment of the present invention. In this embodiment, the tuning circuit for a pivotal antenna comprises a feeder transmission cable 11, a microwave medium 12, an impedance-matching tuning circuit 13, a grounding plane 14, a pivotal shaft 15, a radiation conductor 16, and a carrier member 17.

The feeder transmission cable 11 is a high-frequency coaxial feeder cable and has a central wire 111, an insulating layer 112, an outer conductor 113 and a coating layer 114 from center to surface. The microwave medium 12 has a first plane 121 and a second plane 122 electrically isolated from the first plane 121. The impedance-matching tuning circuit 13 is arranged on the first plane 121 of the microwave medium 12 and connected with the central wire 111. The impedance-matching tuning circuit 13 is used to modify the impedance and bandwidth of the antenna system. The impedance-matching tuning circuit 13 is realized with a chip in the present invention. The grounding plane 14 is arranged on the second plane 122 of the microwave medium 12 and connected with the outer conductor 113. The pivotal shaft 15 has a first end 151 and a second end 152, which respectively extend along opposite directions. The first end 151 of the pivotal shaft 15 is connected with the impedance-matching tuning circuit 13, and the second end 152 of the pivotal shaft 15 is connected with the radiation conductor 16. The pivotal shaft 15 is a rotation shaft of a common wireless transmission device and normally made of a metal. The radiation conductor 16 is a metal plate in the present invention. The carrier member 17 accommodates the microwave medium 12 thereinside. The carrier member 17 is a baseplate of a portable computer 1 or a mobile phone. In this embodiment, the carrier member 17 is a baseplate of a portable computer 1.

When an impedance-matching tuning activity is undertaken, radiation signals are transmitted along the path indicated by arrows. As soon as the feeder transmission cable 11 transfers high-frequency feed-in signals to the chip of the impedance-matching tuning circuit 13, the impedance-matching tuning circuit 13 performs circuit switching to tune impedance and bandwidth. Tuned signals are transferred to the pivotal shaft 15 and then to the radiation conductor 16 to undertake radiation energy conduction.

The microwave medium 12 has a rectangular shape with a length of about 40 mm, a width of about 18 mm and a thickness of about 1 mm. The impedance-matching tuning circuit 13 is a circuit substrate having a rectangular shape with a length of about 13 mm, a width of about 6 mm and a thickness of about 0.5 mm. The grounding plane 14 has an about U shape. The U-shape grounding plane 13 may be divided into two rectangles at two sides of the impedance-matching tuning circuit 13 and a long rectangle below the impedance-matching tuning circuit 13. The two rectangles at two sides of the impedance-matching tuning circuit 13 have identical area, and each has a length of about 6 mm and a width of about 5 mm. The underneath long rectangle has a length of about 40 mm and a width of about 12 mm. The pivotal shaft 15 is a column-like structure having a length of about 22 mm and a width of about 5 mm. The radiation conductor 16 is a metal plate of an outer frame of a notebook computer, and the central region thereof is hollow. The carrier member 17 is a baseplate of the notebook computer. The radiation conductor 16 and the carrier member 17 have about identical area. The radiation conductor 15 has a length of about 290 mm and a width of about 220 mm, and the hollow region thereof has a length of about 25 mm and a width of about 18 mm.

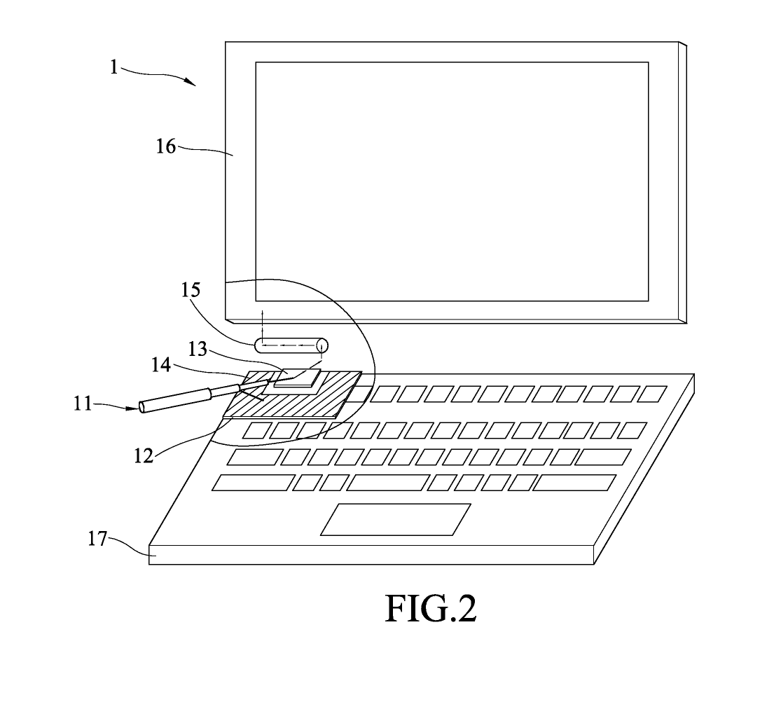

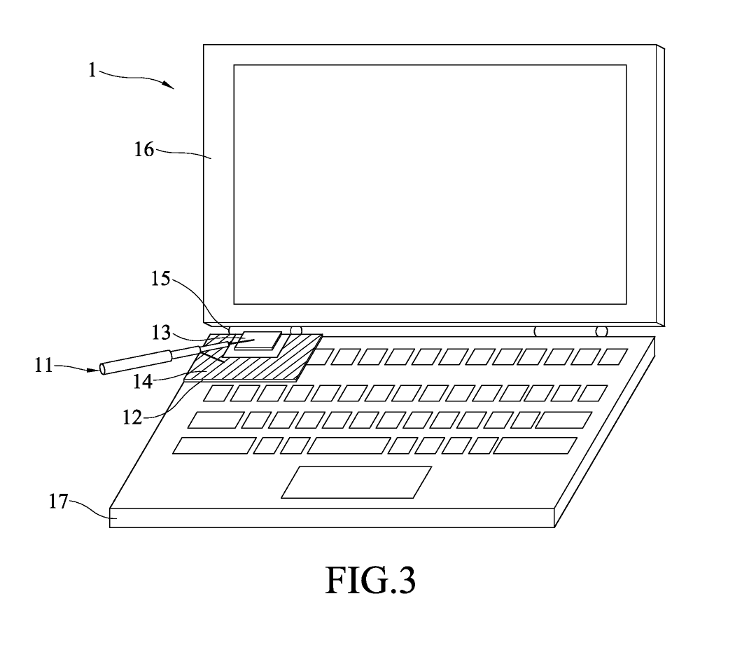

Refer to FIG. 2 and FIG. 3 respectively a perspective exploded view and a perspective assembly drawing according to the first embodiment of the present invention. The first embodiment is characterized in that a tuning circuit chip is arranged in the elbow near the pivotal shaft. As soon as the feeder transmission cable 11 transfers high-frequency feed-in signals of the antenna system to the chip of the impedance-matching circuit 13, the impedance-matching tuning circuit 13 fine-tunes the impedance and bandwidth of the antenna system according to impedance adjusting procedures. The tuned radiation signals are transmitted to the pivotal shaft 15 and then to the radiation conductor 16 to undertake radiation energy conduction. Thereby is increased the bandwidth and efficiency and raised the signal transceiving intensity and transmission performance stability.

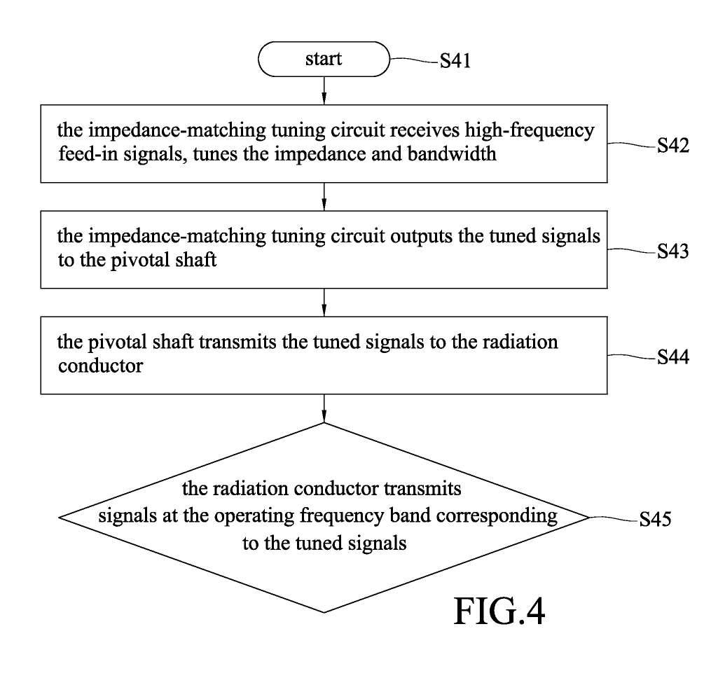

Refer to FIG. 4 a flowchart according to the first embodiment of the present invention. In Step S41, the system begins to operate. In Step S42, the impedance-matching tuning circuit receives high-frequency feed-in signals, tunes the impedance and bandwidth. In Step S43, the impedance-matching tuning circuit outputs the tuned signals to the pivotal shaft. In Step S44, the pivotal shaft transmits the tuned signals to the radiation conductor. In Step S45, the radiation conductor transmits signals at the operating frequency band corresponding to the tuned signals.

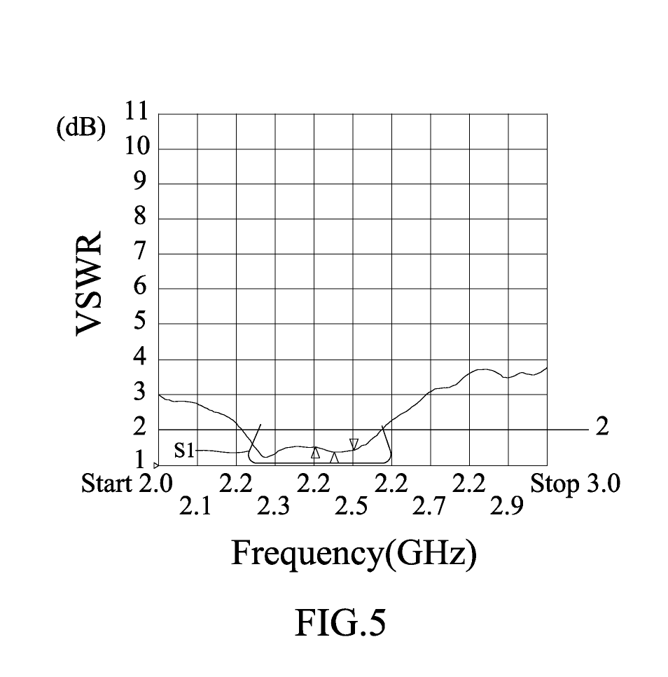

Refer to FIG. 5 a diagram showing the measurement results of the voltage standing wave ratio (VSWR) of the tuning circuit for a pivotal antenna according to the first embodiment of the present invention, wherein the horizontal axis represents frequency and the vertical axis represents dB. FIG. 5 shows that the operational frequency band S1 ranges from 2.2 GHz to 2.6 GHz, which covers the frequency bands of the WLAN 802.11b/g system and the WiMAX 2.3G system. In the standards, an antenna is required to have VSWR lower than 3. Otherwise, the antenna would not have the required performance. FIG. 5 shows that VSWR is lower than 3 in all the frequency bands and lower than 2 in most of the frequency bands. Thus, the operating bandwidth is greatly increased. Therefore, FIG. 5 proves that the operating bandwidth of the present invention can satisfy the design requirement.

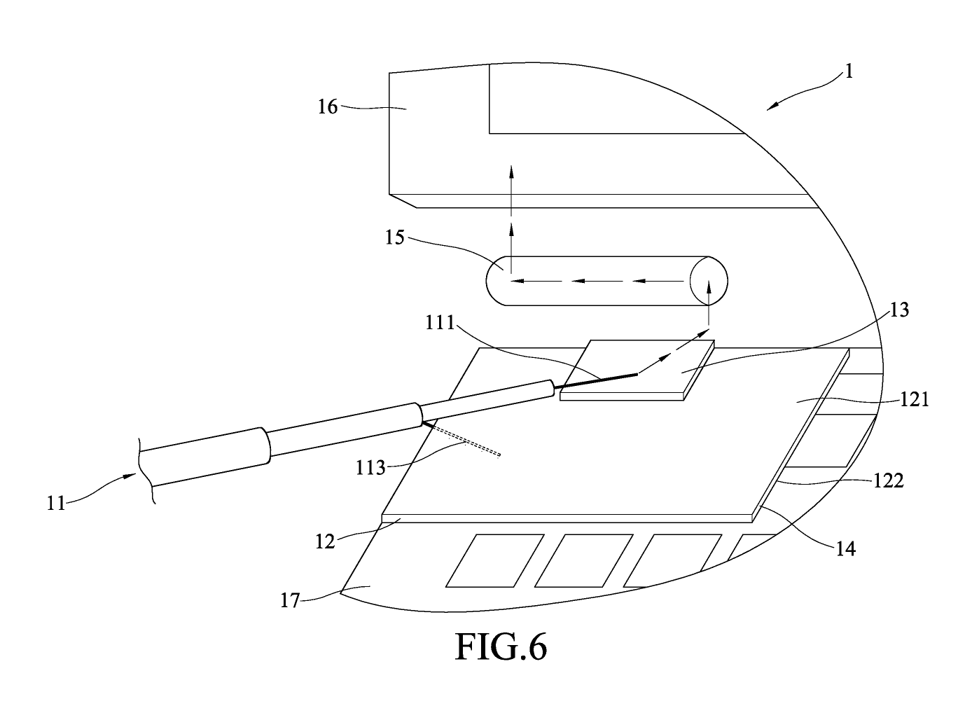

Refer to FIG. 6 a partially-enlarged perspective view schematically showing that the tuning circuit for a pivotal antenna of the present invention is applied to a portable computer according to a second embodiment of the present invention. The second embodiment is basically similar to the first embodiment. The second embodiment is different from the first embodiment in that the first plane 121 of the microwave medium 12 is faced upward and that the second plane 122 is faced downward. Thus, the first and second plane 121 and 122 are also electrically separated in the second embodiment. Similarly, the central wire 111 is connected with the impedance-matching tuning circuit 13, and the outer conductor 113 is connected with the lower surface of the grounding plane 14. The transmission path and transmission way of the impedance-matching tuning circuit 13 in the second embodiment are the same as those in the first embodiment.

No matter how the shape and appearance of the microwave medium 12 varies with the interior design of a product, the antenna layout of the present invention can always be flexibly arranged according to the principle of the present invention.

The present invention possesses utility, novelty and non-obviousness and meets the condition for a patent. Thus, the Inventors file the application. It is appreciated if the patent is approved fast.

The embodiments are only to exemplify the present invention but not to limit the scope of the present invention. Any equivalent modification or variation according to the spirit of the present invention is to be also included within the scope of the present invention.

What is claimed is:

1. A tuning circuit for a pivotal antenna, comprising
a feeder transmission cable having a central wire and an outer conductor;
a microwave medium having a first plane and a second plane;
an impedance-matching tuning circuit arranged on said first plane of said microwave medium and connected with said the central wire;
a grounding plane arranged on said second plane of said microwave medium and connected with said outer conductor;
a pivotal shaft having a first end and a second end, wherein said impedance-matching tuning circuit is connected with said first end of said pivotal shaft;
a radiation conductor connected with said second end of said pivotal shaft; and
a carrier member accommodating said microwave medium.

2. The tuning circuit for a pivotal antenna according to claim 1, wherein said impedance-matching tuning circuit is used to tune impedance and bandwidth of an antenna system.

3. The tuning circuit for a pivotal antenna according to claim 1, wherein said impedance-matching tuning circuit is a circuit chip.

4. The tuning circuit for a pivotal antenna according to claim 1, wherein said impedance-matching tuning circuit is a component printed on said microwave medium.

5. The tuning circuit for a pivotal antenna according to claim 1, wherein said first end and said second end of said pivotal shaft respectively extend along opposite directions.

6. The tuning circuit for a pivotal antenna according to claim 1, wherein said pivotal shaft is a rotation shaft.

7. The tuning circuit for a pivotal antenna according to claim 1, wherein said pivotal shaft is made of a metallic material.

8. The tuning circuit for a pivotal antenna according to claim 1, wherein said radiation conductor is a metal plate of a notebook computer or a mobile phone.

9. The tuning circuit for a pivotal antenna according to claim 1, wherein said carrier member is a baseplate of a notebook computer or a mobile phone.
